(19) United States
(12) Patent Application Publication
(10) Pub. No.: US 2016/0276288 A1
(43) Pub. Date: Sep. 22, 2016

(54) SEMICONDUCTOR PACKAGE AND SEMICONDUCTOR DEVICE INCLUDING ELECTROMAGNETIC WAVE SHIELD LAYER

(71) Applicant: Samsung Electronics Co., Ltd., Suwon-si (KR)

(72) Inventors: Baik-woo LEE, Gwangmyeong-si (KR); Young-jae KIM, Hwaseong-si (KR)

(21) Appl. No.: 14/960,443

(22) Filed: Dec. 7, 2015

(30) Foreign Application Priority Data
Mar. 16, 2015 (KR) 10-2015-0036188

(51) Int. Cl. H01L 23/552; H01L 23/31

(52) U.S. Cl. CPC H01L 23/552; H01L 23/3107

(57) ABSTRACT

A semiconductor package is provided with an electromagnetic wave shielding layer, and a conductive ground layer connected thereto. For example, in certain embodiments, the conductive ground layer is formed in a package substrate of the semiconductor package. The conductive ground layer may include a planar, or base portion, and a protruding, or lip portion. The planar or base portion as well as the protruding or lip portion may contact the electromagnetic wave shielding layer surrounding the semiconductor package.

### CROSS-REFERENCE TO RELATED APPLICATION

This application claims the benefit of Korean Patent Application No. 10-2015-0036188, filed on Mar. 16, 2015, in the Korean Intellectual Property Office, the disclosure of which is incorporated herein in its entirety by reference.

### BACKGROUND

This disclosure relates to a semiconductor package and semiconductor package substrate for shielding against electromagnetic interference (EMI).

Due to miniaturization of electronic devices and increase in a data transmission rate, electromagnetic interference (EMI) degrades performance of semiconductor packages. Therefore, studies have been going on to shield against the EMI emitted from electronic devices.

### SUMMARY

According to various embodiments, a semiconductor package is provided with an electromagnetic wave shielding layer, and a conductive ground layer connected thereto. For example, in certain embodiments, the conductive ground layer is formed in a package substrate of the semiconductor package. The conductive ground layer may include a planar, or base portion, and a protruding, or lip portion. The planar or base portion as well as the protruding or lip portion may contact the electromagnetic wave shielding layer surrounding the semiconductor package. Additional details of the various embodiments will be described below.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a semiconductor package which is attached on to a main board, according to an exemplary embodiment of the inventive concept;

FIGS. 2A and 2B are cross-sectional views of a semiconductor package, according to an exemplary embodiment of the inventive concept;

FIGS. 3A to 3E are schematic plan views of an edge of a ground layer in which a protruding portion is formed, in a semiconductor package according to an exemplary embodiment of the inventive concept;

FIGS. 4A and 4B are cross-sectional views of a semiconductor package, according to another exemplary embodiment of the inventive concept;

FIG. 5 is a cross-sectional view of a semiconductor package, according to another exemplary embodiment of the inventive concept;

FIG. 6 is a cross-sectional view of a semiconductor package, according to another exemplary embodiment of the inventive concept;

FIGS. 7A to 7K are cross-sectional views of a manufacturing method of a semiconductor package, according to an exemplary embodiment of the inventive concept;

FIGS. 8A to 8D are cross-sectional views of a manufacturing method of a semiconductor package, according to another exemplary embodiment of the inventive concept;

FIGS. 9A to 9C are cross-sectional views of a manufacturing method of a semiconductor package, according to another exemplary embodiment of the inventive concept;

FIG. 10 a structural block diagram of a memory card according to an exemplary embodiment of the inventive concept;

FIG. 11 is a structural block diagram of an electronic system according to an exemplary embodiment of the inventive concept; and

FIG. 12 is a perspective view of an electronic device to which a semiconductor package according to an exemplary embodiment of the inventive concept may be applied.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

Various aspects of the inventive concept will be described more fully hereinafter with reference to the accompanying drawings, in which exemplary embodiments of the inventive concept are shown. This inventive concept may, however, be embodied in many different forms and should not be construed as limited to the exemplary embodiments set forth herein.

In the drawings, the sizes of layers and regions may be exaggerated for clarity. The same reference numerals are used to denote the same elements, and repeated descriptions thereof will be omitted.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms “first,” “second,” etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the inventive concept. In addition, in certain cases, even if a term is not described using “first,” “second,” etc., in the specification, it may still be referred to as “first” or “second” in a claim in order to distinguish different claimed elements from each other.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Meanwhile, spatially relative terms, such as “between” and “directly between” or “adjacent to” and “directly adjacent to” and the like, which are used herein for ease of description to describe one element or feature's relationship to another element(s) or feature(s) as illustrated in the figures, should be interpreted similarly. However, the term “contact,” as used herein refers to direct contact (i.e., touching) unless the context indicates otherwise.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes,” and/or “including,” if used herein, specify the presence of stated features, integers, steps, operations, elements and/or components, but do not preclude the presence or addition of one or more other features, integers, steps, operations, elements, components and/or groups thereof.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless explicitly so defined herein.

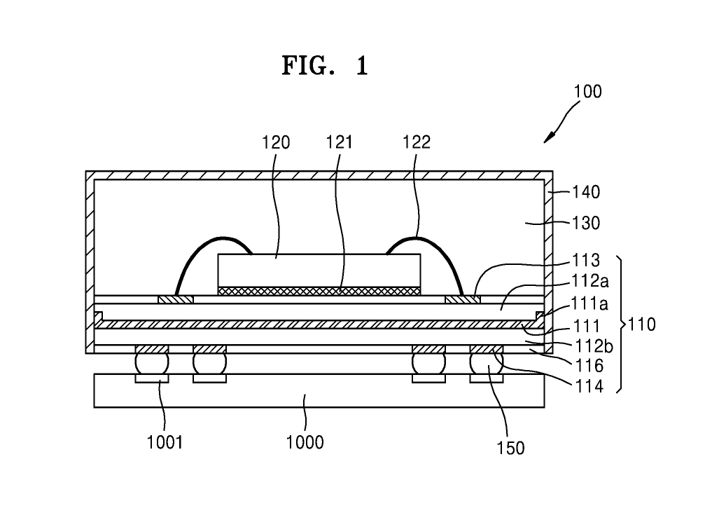

FIG. 1 is a cross-sectional view of a semiconductor package 100, which is attached on a main board 1000, according to an exemplary embodiment of the inventive concept.

Referring to FIG. 1, the semiconductor package 100 may be electrically connected to the main board 1000 via a connection pad 1001 disposed on one surface of the main board 1000 and an external connection terminal 150.

The semiconductor package 100 may include a substrate 110 including a ground layer 111, a semiconductor chip 120 formed on one surface of the substrate 110, a mold member 130 formed on one surface of the substrate 110 and covering the semiconductor chip 120, an electromagnetic wave shielding member 140 surrounding a lateral (e.g., side) surface of the substrate 110 and the semiconductor chip 120 and contacting an edge of the ground layer 111, and the external connection terminal 150.

Though individual components are either shown or described, the embodiments are not limited as such. For example, one or more semiconductor chips, such as depicted for 120, may be disposed on the substrate 110, which may be referred to herein as a package substrate. The one or more semiconductor chips may include, for example, a stack of chips, to form a chip stack package. Various types of stacked chip configurations and connections are known in the art. In addition, though one external connection terminal 150 is referenced above, as can be seen in FIG. 1 and other figures, a plurality of external connection terminals are included in the semiconductor package 100. It should also be noted that the device including the substrate 110, one or more semiconductor chips (e.g., 120), the mold member 130, and the external connection terminals 150 may be referred to herein as a semiconductor package, or a semiconductor device. These components combined with the electromagnetic shielding member 140 may be referred to as a semiconductor device, or semiconductor package.

For example, as used herein, a semiconductor device may refer to any of the various devices such as shown in FIG. 1, 2A, 2B, 4A, 4B, 5, or 6, and may also refer, for example, to a device such as a semiconductor chip (e.g., memory chip and/or logic chip formed on a die), a stack of semiconductor chips, a semiconductor package including one or more semiconductor chips stacked on a package substrate and optionally covered with a mold member, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, a hard drive including additional components, or a mobile phone, laptop, tablet, desktop, camera, or other consumer electronic device, etc.

The substrate 110 may include the ground layer 111, a first wiring 113, a second wiring 114, a first body portion 112a, a second body portion 112b, and a solder resist layer 116.

The first and second body portions 112a and 112b may be formed and the ground layer 111 may be interposed therebetween. The first and second body portions 112a and 112b may be formed, for example, by a semi-cured prepreg formed by permeating epoxy resin, polyamide resin, bismaleimide resin, or phenolic resin which are uncured by organic fiber such as glass fiber and aramid resin, but are not limited thereto. The package substrate 110 may include a core, formed of an electrically insulating material. For example, the core may include first and second body portions 112a and 112b described above, which may be described as first and second core portions.

The first wiring 113 may be formed on an upper surface of the first body portion 112a and may be exposed to one surface of the substrate 110. The second wiring 114 may be formed on a lower surface of the second body portion 112b and may be exposed to another surface of the substrate 110 (e.g., an opposite surface to a top surface of the package substrate). The first and second wirings 113 and 114 may be formed, for example, of a metal foil with a predetermined thickness by a patterning technique using an etching process such as photolithography but are limited thereto, and may further be formed of other electroconductive material having excellent electrical characteristics.

The ground layer 111 may be formed between the first and second body portions 112a and 112b, and a part of the ground layer 111 may contact the electromagnetic wave shielding member 140. The ground layer 111 may therefore be formed in or within the core of the package substrate 110. In some embodiments, the ground layer 111 is electrically connected to the electromagnetic wave shielding member 140 and may be provided as an electrical path to ground electromagnetic interference (EMI) incident to the electromagnetic wave shielding member 140. In an exemplary embodiment, the ground layer 111 may be formed of copper (Cu) having an electric resistance ratio of about 1.67×10⁻⁸ Ωm at 20° C. and it may be more advantageous to ground electromagnetic waves in this manner compared to using a solder bump having an electric resistance ratio of about 20.7×10⁻⁸ Ωm at 20° C. as a grounding element. However, the forming material of the ground layer 111 is not limited to Cu, and the ground layer 111 may be formed of different conductive materials, for example, a metal such as silver (Ag) or gold (Au), a metal alloy such as Cu—Ag, titanium (Ti)—Ag—Cu, or Cu-zinc (Zn), or materials having a different electrical conductivity.

The ground layer 111 acts as a path to shield against the EMI and is included in the substrate 110. Therefore, additional processes for forming other grounding elements, for example, a conductive bump or a metal pad on the substrate 110 are not required, and thus damage caused by heat generated by forming the grounding element on the ground layer 111 and recessing of the substrate 110 does not occur. As a result, a fraction defective of a device including a semiconductor package may be reduced.

In some embodiments, the substrate 110 may include a plated through hole or a metal blind electrically connecting the first wiring 113, the second wiring 114 and the ground layer 111. As such, at least a first vertical conductive line may be electrically connected to a first external terminal 150 of the plurality of external terminals, and electrically connected to the ground layer 111, which may be referred to herein as a conductive ground layer.

The solder resist layer 116 may be formed on a portion in which the first and second wirings 113 and 114 are not formed, from among the upper surface of the first body portion 112a and the lower surface of the second body portion 112b.

The external connection terminals 150 may be formed on another surface of the substrate 110, and furthermore, may be disposed at a position corresponding to the second wiring 114 and electrically connected to the second wiring 114. The external connection terminal 150 may be a solder ball but is not limited thereto, and may be a conductive bump, a conductive spacer, or a pin grid array.

The semiconductor chip 120, or a plurality of semiconductor chips may be formed on one surface of the substrate 110. The semiconductor chip 120 may be manufactured by using silicon, silicon on insulator (SOI), or silicon germanium, but is not limited thereto, and may be formed as a die singulated from a wafer. Multilayer wiring, a plurality of transistors, and/or a plurality of passive elements may be integrated in the semiconductor chip 120. The semiconductor chip 120 and the substrate 110 may be bonded by an adhesive layer 121 interposed therebetween and may be electrically connected by bonding of wires 122. The wires 122 are wires for semiconductor bonding and may include at least one from among Au, Ag, platinum (Pt), aluminum (Al), Cu, palladium (Pd), nickel (Ni), cobalt (Co), chrome (Cr) and titanium (Ti), and may be formed by a wire bonding device. However, the semiconductor chip 120 may be mounted on the substrate 110 by other methods such as flip chip bonding, using through substrate vias (TSVs), or by other known techniques.

In some embodiments, the conductive ground layer 111 is electrically connected to at least a first terminal of the plurality of external terminals 150, and the first terminal is electrically connected to circuitry of the one or more semiconductor chips designated for connecting to a ground. For example, the circuitry may include one or more active or passive elements designed to receive a ground potential during operation. The first terminal may be a ground terminal. For example, the first terminal may connect through a conductive through via (e.g., a TSV) or through internal wiring of the package substrate 110 to the conductive ground layer 111, and to a pad or other terminal on the semiconductor chip 120 that provides an applied ground potential to an integrated circuit of the semiconductor chip 120. Thus, the first terminal may be for connecting to a ground of an external device or power source, such that in some instances, if the terminal were to connect to another voltage source having a level other than ground, the semiconductor chip 120 would not function properly.

The electromagnetic wave shielding member 140 may be formed to surround the lateral surface of the substrate 110 and the semiconductor chip 120, and may be disposed to contact the ground layer 111. In some embodiments, for example, the electromagnetic wave shielding member 140 is formed to surround lateral (e.g., side) surfaces and cover a top surface of the mold member 130 as well as to surround lateral (e.g., side) surfaces of the package substrate 110. The electromagnetic wave shielding member 140 may contact the side surfaces and a top surface of the mold member as well as the side surfaces of the package substrate 110. In one embodiment where the mold member 130 covers a top surface of one or more semiconductor chips 120, the electromagnetic wave shielding member 140 may entirely cover and contact a top surface of the mold member 130. The electromagnetic wave shielding member 140 may include a conductive material such as Cu, Ag, or Pt, and may include a conductive material formed of a conductive layer in an exemplary embodiment. The electromagnetic wave shielding member 140 may be formed by including the conductive layer formed of Cu, Ag, or Pt, on a thin cover including a space surrounding the semiconductor chip 120. Furthermore, the electromagnetic wave shielding member 140 may have a thickness of, for example, 1 to 50 μm. The electromagnetic wave shielding member 140 may also be referred to herein as an electromagnetic wave shield, an electromagnetic wave shield layer, an EMI shield, or EMI shielding layer.

Methods such as chemical vapor deposition (CVD), electroless plating, electrolytic plating, spraying, or sputtering may be used to form the conductive layer that forms the electromagnetic wave shielding member 140.

The semiconductor package 100 may include the mold member 130 formed on one surface of the substrate 110 and the mold member 130 molds the semiconductor chip 120. The mold member 130 may be an epoxy molding compound (EMC) or an underfill material, but is not limited thereto. The mold member 130 may also be referred to as an encapsulation layer, or encapsulant.

An electromagnetic wave scattered from the semiconductor chip 120 is shielded against by the electromagnetic wave shielding member 140, and this may reduce influence on another adjacent semiconductor device. Furthermore, an electromagnetic wave scattered from the adjacent semiconductor device is also shielded against by the electromagnetic wave shielding member 140, and thus may reduce its influence on the semiconductor chip 120. The conductive ground layer 111 may further assist in shielding electromagnetic waves to and from the semiconductor chip 120.

Furthermore, a semiconductor package according to an exemplary embodiment of the inventive concept does not need an EMI shielding can for shielding against EMI. Therefore, problems that arise as a result of a shielding can being adhered to a semiconductor device by an adhesive (e.g., issues such as being separated from the semiconductor device by reduced adhesive strength due to surrounding environmental conditions such as temperature or humidity) do not occur. Manufacturing time and manufacturing costs with respect to the semiconductor package may be reduced due to not having to form the shielding can, which needs to be made within a relatively small allowable error. Therefore, it is advantageous to miniaturize an electronic device.

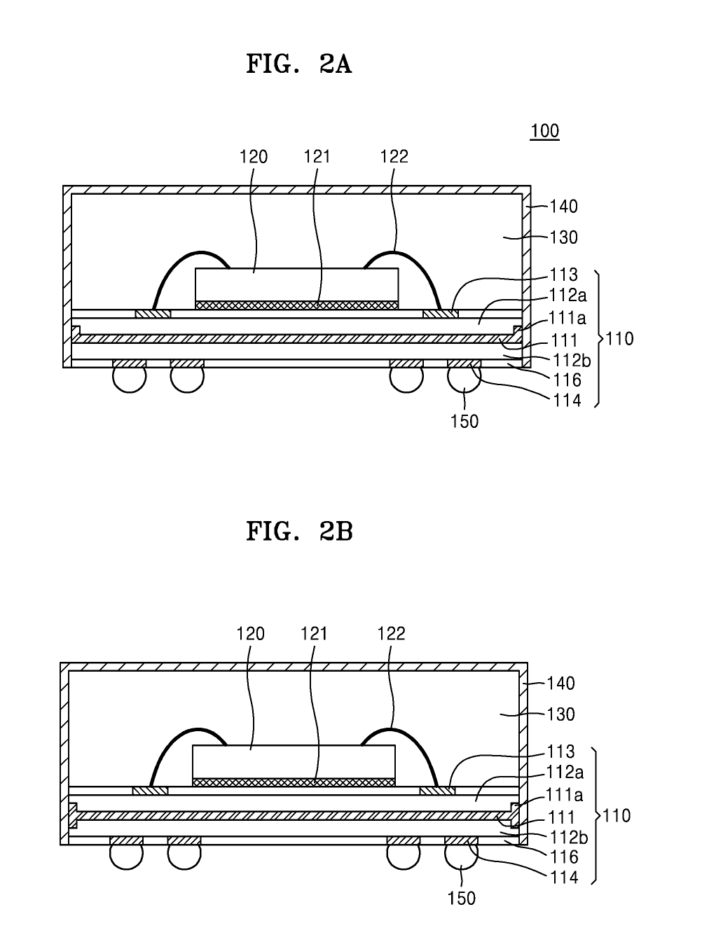

Referring to FIG. 2A or 2B, in some embodiments, the ground layer 111 includes a protruding portion 111a on an edge thereof and the protruding portion 111a contacts the electromagnetic wave shielding member 140. As such, the ground layer 111 may have a plate shape, including a planar portion and a protruding portion protruding therefrom. The protruding portion may extend above and/or below the planar portion, as shown in FIGS. 2A and 2B. The planar portion and protruding portion may be continually, and integrally formed, for example, of the same material. The ground layer 111 may also be described as including a base portion and a lip portion, wherein the lip portion extends above and/or below the base portion. As the protruding portion 111a is formed on the edge of the ground layer 111 meeting the electromagnetic wave shielding member 140, a contact resistance may be reduced by increasing the contact area between the electromagnetic wave shielding member 140 and the ground layer 111. Therefore, an EMI shielding effect is increased in the semiconductor package.

The protruding portion 111a may be extended in a direction perpendicular to one surface of the ground layer 111 from a portion meeting the electromagnetic wave shielding member 140. The one surface of the ground layer 111 may refer to an upper surface or a lower surface of the base portion of the ground layer 111.

The protruding portion 111a may be formed to extend from the upper surface and/or the lower surface of the base portion of the ground layer 111 and may be extended along an outer periphery of the ground layer 111. The protruding portion 111a may extend along the outer periphery of the ground layer 111.

In some embodiments, the planar portion and the protruding portion of the conductive ground layer form part of a side surface of the package substrate and contact the electromagnetic wave shield layer. In some embodiments, the side surfaces of the package substrate 110 and the side surfaces of the mold member 130 are coplanar, such that an EMI shield (e.g., 140) covering each of these surfaces has a planar shape.

As can been seen in FIGS. 2A and 2B, the plurality of external terminals 150 may be disposed below the conductive ground layer 111 to electrically connect circuitry in the package substrate 110 to an external device external to the semiconductor package. In addition, one or more semiconductor chips 120 may be disposed above the conductive ground layer 111, and may be electrically connected to the package substrate 110. The conductive ground layer 111 may be electrically connected to at least a first terminal of the plurality of external terminals, and the first terminal may be electrically connected to circuitry of the one or more semiconductor chips designated for connecting to a ground.

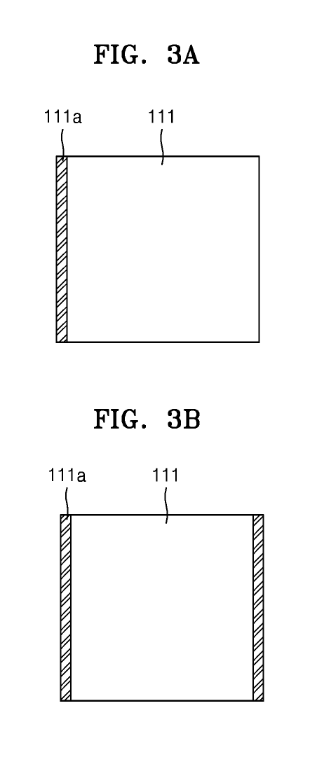

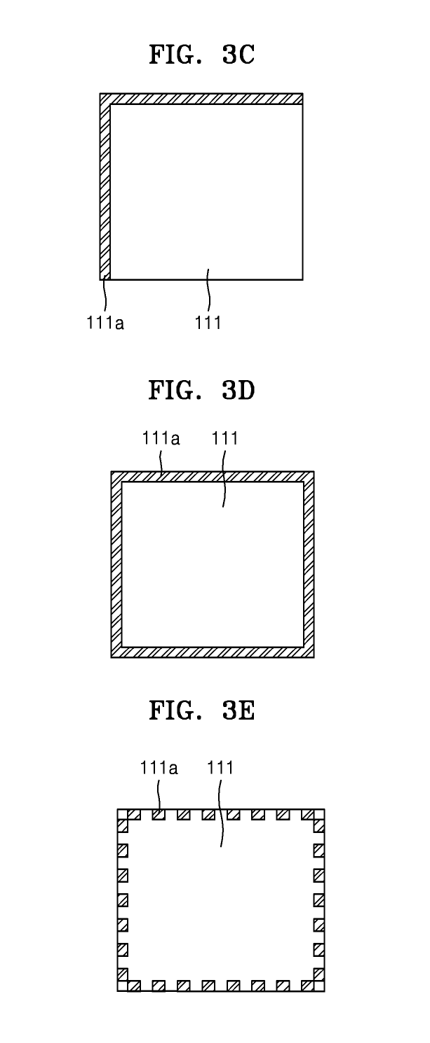

FIGS. 3A to 3E are plan views of an edge of the ground layer 111 in which a protruding portion 111a is formed, in a semiconductor package according to an exemplary embodiment of the inventive concept.

Referring to FIGS. 3A to 3E, from the plan view perspective, the protruding portion 111a may be continuously formed on any one edge of outer peripheries of the ground layer 111 (FIG. 3A), continuously formed on a pair of edges facing each other of outer peripheries of the ground layer 111 (FIG. 3B), continuously formed on a pair of edges contacting each other of outer peripheries of the ground layer 111 (FIG. 3C), or continuously formed on three edges or all edges of outer peripheries of the ground layer 111 (FIG. 3D). Furthermore, the protruding portion 111a may be discontinuously formed on outer peripheries of the ground layer 111 contacting the electromagnetic wave shielding member 140 (FIG. 3E).

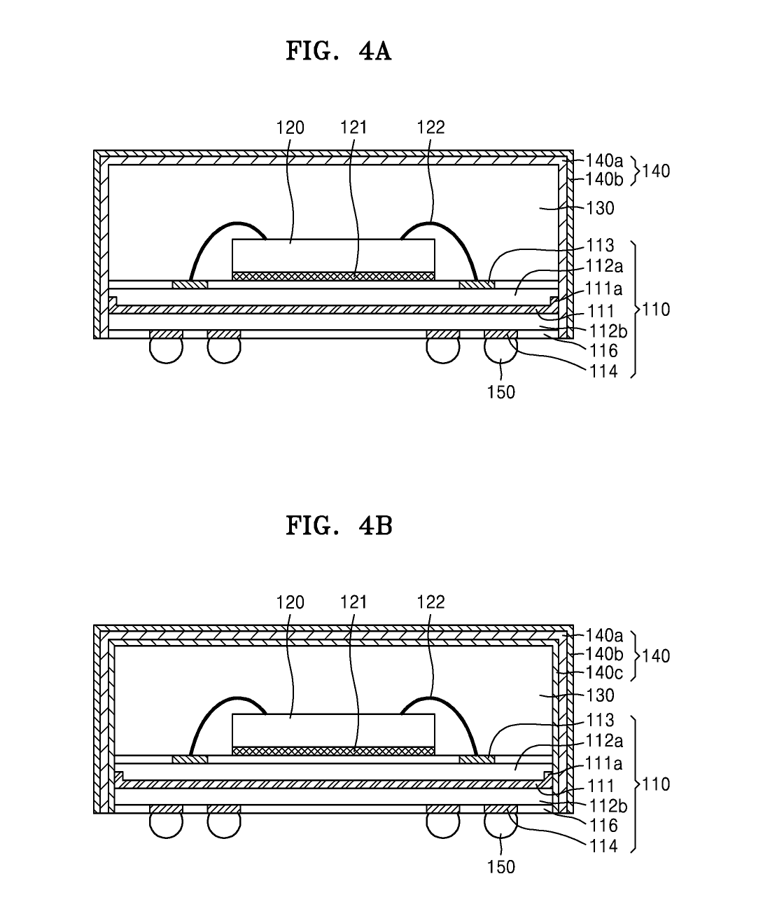

Referring to FIG. 4A, in an exemplary embodiment, the electromagnetic wave shielding member 140 may include first and second electromagnetic wave shielding members 140a and 140b. The first electromagnetic wave shielding member 140a may be formed to contact the ground layer 111 while surrounding a lateral surface of the substrate 110 and the semiconductor chip 120. Furthermore, the first electromagnetic wave shielding member 140a may have a thickness of, for example, 1 to 50 μm and may include a conductive layer such as Cu or Ag. The second electromagnetic wave shielding member 140b may be exposed by surrounding the first electromagnetic wave shielding member 140a and may have a thickness, for example, of 50 to 300 nm. Furthermore, the second electromagnetic wave shielding member 140b may be formed of a layer of nickel (Ni) or stainless steel to prevent the first electromagnetic wave shielding member 140a from being oxidized or exposed to a wet environment.

Referring to FIG. 4B, in another exemplary embodiment, the electromagnetic wave shielding member 140 may include the first electromagnetic wave shielding member 140a, the second electromagnetic wave shielding member 140b, and a third electromagnetic wave shielding member 140c located between the substrate 110 and the first electromagnetic wave shielding member 140a. The third electromagnetic wave shielding member 140c may be formed to surround a lateral surface of the substrate 110 and the semiconductor chip 120 and may have a thickness, for example, of 50 to 300 nm. The third electromagnetic wave shielding member 140c may be formed of a layer including a material such as Ni, Ti, Cr, or stainless steel, and thus an adhesive strength between the electromagnetic wave shielding members 140 and the substrate 110 is increased and separating of the electromagnetic wave shielding members 140 may be prevented. The first electromagnetic wave shielding member 140a may be formed between the third electromagnetic wave shielding member 140c and the second electromagnetic wave shielding member 140b and may have a thickness, for example, of 1 to 50 μm, and may further include a conductive layer formed of Cu or Ag. The second electromagnetic wave shielding member 140b may be formed to surround the first electromagnetic wave shielding member 140a and be exposed to outside, and may further have a thickness, for example, of 50 to 300 nm. The second electromagnetic wave shielding member 140b may be formed of a layer of Ni or stainless steel to prevent the first electromagnetic wave shielding member 140a from being oxidized or exposed to a wet environment.

A plurality of the electromagnetic wave shielding members 140 may form a plurality of layers by using an identical method or different methods from among CVD, electroless plating, electrolytic plating, spraying, and sputtering.

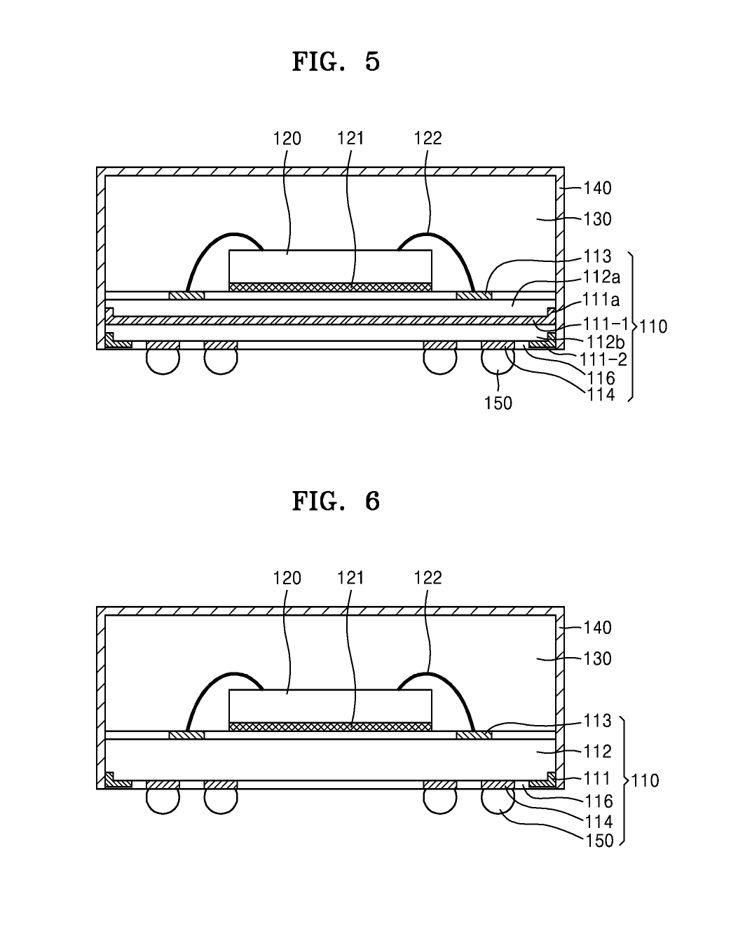

FIG. 5 is a cross-sectional view of a semiconductor package, according to another exemplary embodiment of the inventive concept.

Referring to FIG. 5, a semiconductor package according to another exemplary embodiment of the inventive concept has the same configuration as that of the semiconductor package described above with reference to FIG. 2A in that the semiconductor package may include the substrate 110 including a first ground layer 111-1, the semiconductor chip 120 formed on one surface of the substrate 110, the mold member 130 formed on one surface of the substrate 110 and used to mold the semiconductor chip 120, the electromagnetic wave shielding member 140 surrounding a lateral surface of the substrate 110 and contacting an edge of the first ground layer 111-1, and the external connection terminal 150, in which the substrate 110 may include the first ground layer 111-1, the first wiring 113, the second wiring 114, the first body portion 112a, the second body portion 112b, and the solder resist layer 116, and the first ground layer 111-1 may include a protruding portion in a part contacting the electromagnetic wave shielding member 140. The substrate 110 further includes a second ground layer 111-2 formed on the lower surface of the second body portion 112b.

The second ground layer 111-2 is located on the lower surface of the second body portion 112b and configured to contact the electromagnetic wave shielding member 140 at a side thereof, and thus, may be provided to act as an electrical path to ground an electromagnetic wave.

The second ground layer 111-2 may be formed of conductive materials, for example, a metal such as Cu, Ag, or Au, a metal alloy such as Cu—Ag, Ti—Ag—Cu, Cu—Zn, or other materials having electrical conductivity.

The second ground layer 111-2 may contact the electromagnetic wave shielding member 140 and include a protruding portion formed on an edge thereof. The protruding portion may be formed to be extended along an outer periphery of the second ground layer 111-2 and may be formed on a part of the outer periphery of the second ground layer 111-2.

Furthermore, as shown in FIG. 5, a bottom surface of the second ground layer 111-2 is covered by solder resist layer 116. Thus, in one embodiment, the second ground layer 111-2 is not exposed to the outside of the semiconductor package due to the solder resist layer 116, the second body portion 112b, and the electromagnetic wave shielding member 140 covering the second ground layer 111-2. The second ground layer 111-2, and may be connected to the second wiring 114, for example through internal wiring, and the second wiring 114 may be connected to a ground.

FIG. 6 is a cross-sectional view of a semiconductor package, according to another exemplary embodiment of the inventive concept.

Referring to FIG. 6, the semiconductor package according to another exemplary embodiment of the inventive concept may include the substrate 110, the semiconductor chip 120 formed on one surface of the substrate 110, and the mold member 130 formed on one surface of the substrate 110 and used to mold the semiconductor chip 120, the electromagnetic wave shielding member 140 surrounding a lateral surface of the substrate 110 and contacting the ground layer 111, and the external connection terminal 150, in which the substrate 110 may include the ground layer 111, the first wiring 113, the second wiring 114, a body portion 112, and the solder resist layer 116.

The ground layer 111 is located on a lower surface of the body portion 112 and configured to contact the electromagnetic wave shielding member 140 at a side thereof. Furthermore, the ground layer 111 may be not exposed to the outside due to the solder resist layer 116 covering the ground layer 111, and may be connected to the second wiring 114.

A manufacturing method of a semiconductor package according to an exemplary embodiment of the inventive concept will be described below. Hereinafter, a manufacturing method of a semiconductor package in FIG. 2A will be mainly described. However, the manufacturing method may be applied identically for the same features to a manufacturing method of a semiconductor package according to other exemplary embodiment of the inventive concept. Elements of the semiconductor package described above with reference to FIG. 2A may be applied to the manufacturing method below and repeated descriptions will be omitted.

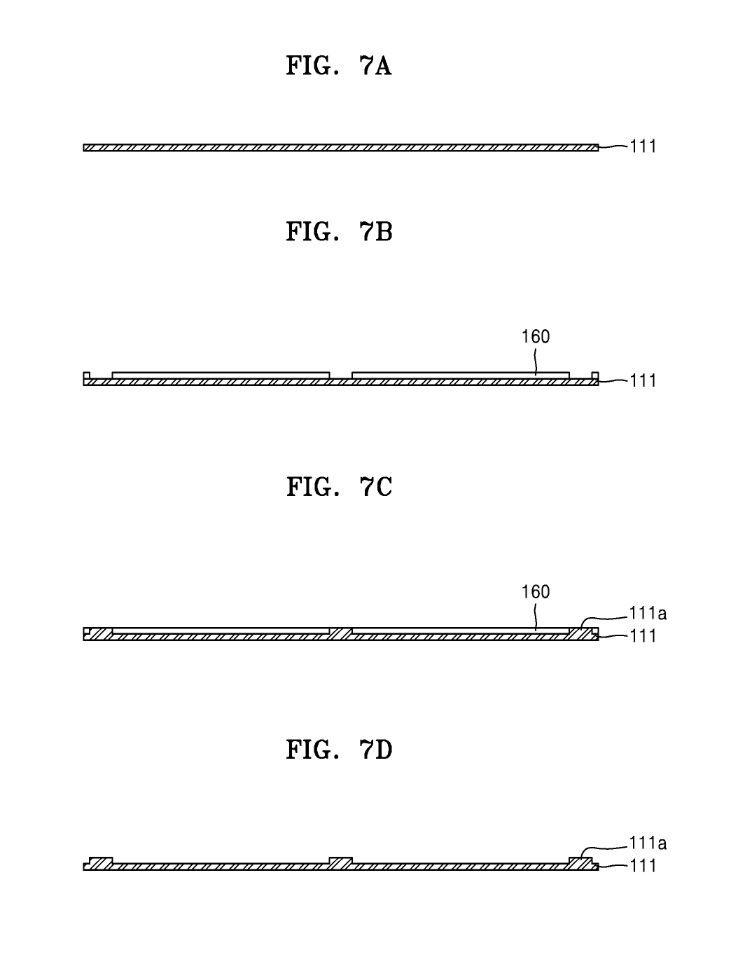

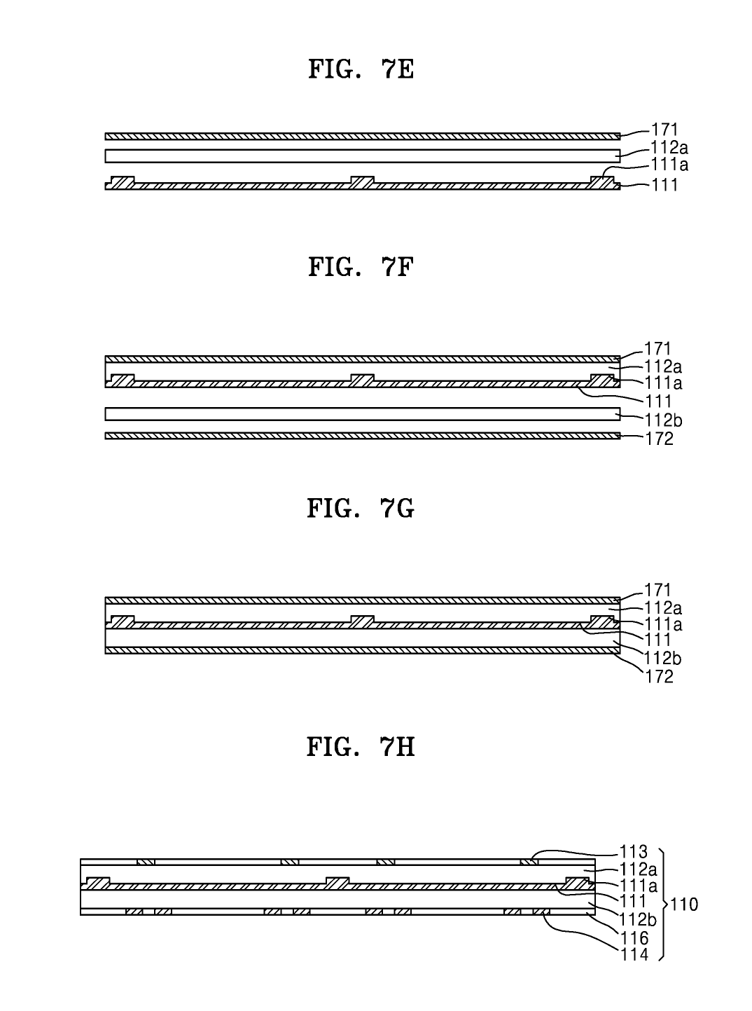

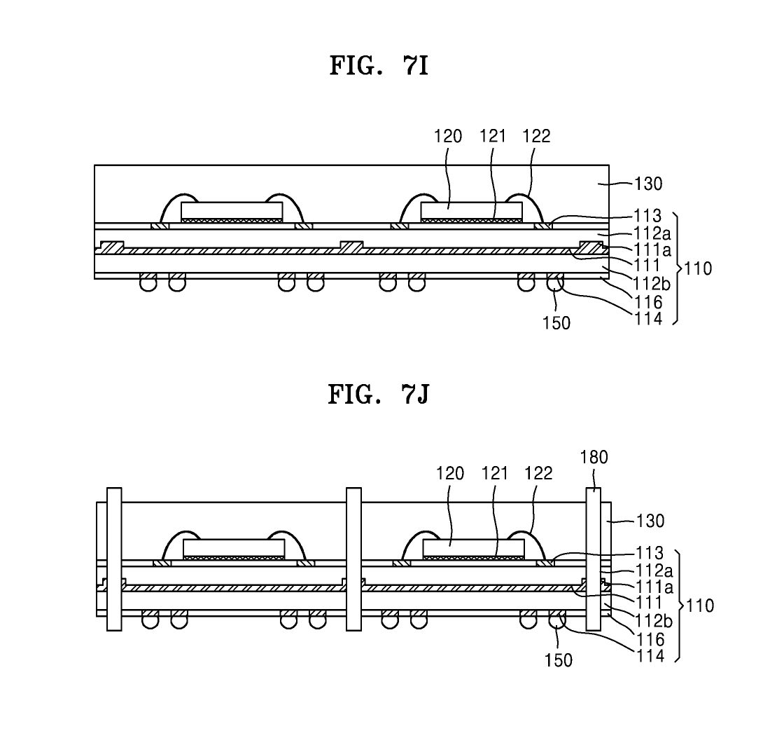

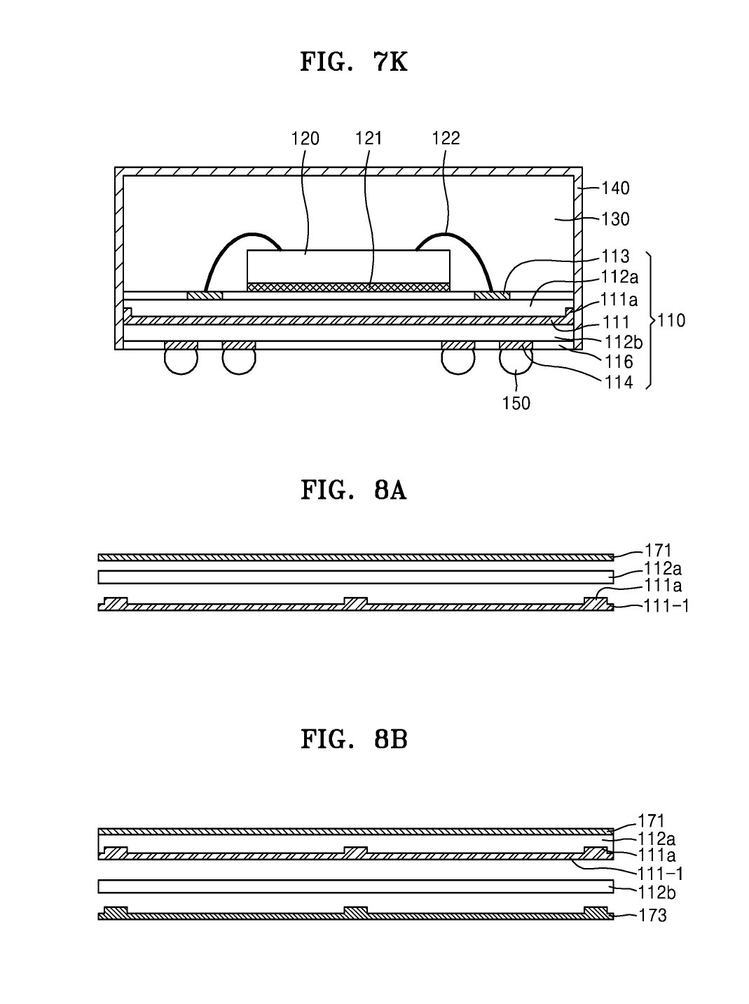

FIGS. 7A to 7D are cross-sectional views of a process of forming the ground layer 111 having a protruding portion 111a according to an exemplary embodiment of the inventive concept.

Referring to FIG. 7A, the plane ground layer 111 having a certain thickness is prepared. In an exemplary embodiment, the ground layer 111 may be formed of Cu but is not limited thereto, and may also be formed of another electrically conductive material.

Referring to FIG. 7B, after compressing and coating a photosensitive dry film 160 on the plane ground layer 111 having the certain thickness, a part in which a protruding portion 111a described below may be formed by patterning the photosensitive dry film 160.

Referring to FIG. 7C, the protruding portion 111a may be formed by electroplating and formed of a conductive material the same as the ground layer 111. In one embodiment, the protruding portion 111a and a base portion of the ground layer 111 are formed of the same material.

Referring to FIG. 7D, the ground layer 111 including the protruding portion 111a may be formed by removing the photosensitive dry film 160 by using a strip process.

FIGS. 7E to 7K are cross-sectional views of a manufacturing method of the semiconductor package of FIG. 2A.

Referring to FIGS. 7E to 7G, the prepared ground layer 111 and a first metal foil 171 are laminated and the first body portion 112a is interposed therebetween. The first metal foil 171 may use a plane metal foil which has conductivity and a certain thickness. Next, the prepared ground layer 111 and a second metal foil 172 are laminated and the second body portion 112b is interposed therebetween. The second metal foil 172 may use a plane metal foil, which has conductivity and a certain thickness.

A laminating process of the second metal foil 172 under a lower surface of the ground layer 111 with the second body portion 112b interposed therebetween has been described as being performed after a laminating process of the first metal foil 171 on an upper surface of the ground layer 111 with the first body portion 112a interposed therebetween, but this is only an example and the inventive concept is not limited thereto.

A semi-cured prepreg may be used as the first and second body portions 112a and 112b.

Referring to FIG. 7H, the first wiring 113 is formed by patterning the first metal foil 171 through an etching process such as a photolithography process. Furthermore, the second wiring 114 is also formed by patterning the second metal foil 172 through an etching process such as a photolithography process.

After this, in order to electrically connect the first and second wirings 113 and 114, and the ground layer 111, a plated through hole or a metal blind via (not shown) in which a metal or other electrically conductive material is covered by using, for example, a plating process after forming the through hole may be formed. Therefore, a conductive through via or conductive line may be formed to connect a first wiring 113 to a second wiring 114, and may electrically connect to the ground layer 111 in between. Furthermore, the solder resist layer 116 may be formed on a part of an upper surface of the first body portion 112a, in which the first wiring 113 is not formed, and on a part of a lower surface of the second body portion 112b, in which the second wiring 114 is not formed.

Referring to FIG. 7I, the semiconductor chip 120 is disposed on one surface of the substrate 110 by using an adhesive layer 121 and may further be mounted to be electrically connected to the first wiring 113 through bonding of the wires 122, but is not limited thereto, and the semiconductor chip 120 may be mounted on the substrate 110 by other methods such as flip chip bonding. Furthermore, the mold member 130 may be formed to mold the semiconductor chip 120 on one surface of the substrate 110 and the external connection terminal 150 may be disposed on another surface of the substrate 110 to electrically connected to the second wiring 114.

Referring to FIG. 7J, the semiconductor package may be divided into individual units through a sawing process and a blade 180 used to perform the sawing process may be located through the protruding portion 111a formed on an edge of the ground layer 111 of the semiconductor package having the individual units. Therefore, an edge area of the ground layer 111 increases contact with the electromagnetic wave shielding member 140 of FIG. 7K.

Referring to FIG. 7K, the electromagnetic wave shielding member 140 may be formed to contact the ground layer 111 while surrounding the lateral surface of the substrate 110 and the semiconductor chip 120. The electromagnetic wave shielding member 140 may include a conductive layer formed of a conductive material and processes like CVD, electroless plating, electrolytic plating, spraying, or sputtering may be used for the electromagnetic wave shielding member 140.

The semiconductor package of FIG. 2B may be manufactured by performing substantially the same process as that of FIGS. 7A to 7D on the opposite surface of one surface of the ground layer 111 to form the protruding portion 111a thereon after forming the protruding portion 111a on the one surface of the ground layer 111 through the process of FIGS. 7A to 7D, and by further performing the process of FIGS. 7E to 7K. Other variations discussed above in connection with FIGS. 1, 2A, 2B, 3A-3E, and 4A and 4B may also be implemented using a method such as described in connection with FIGS. 7A-7K above.

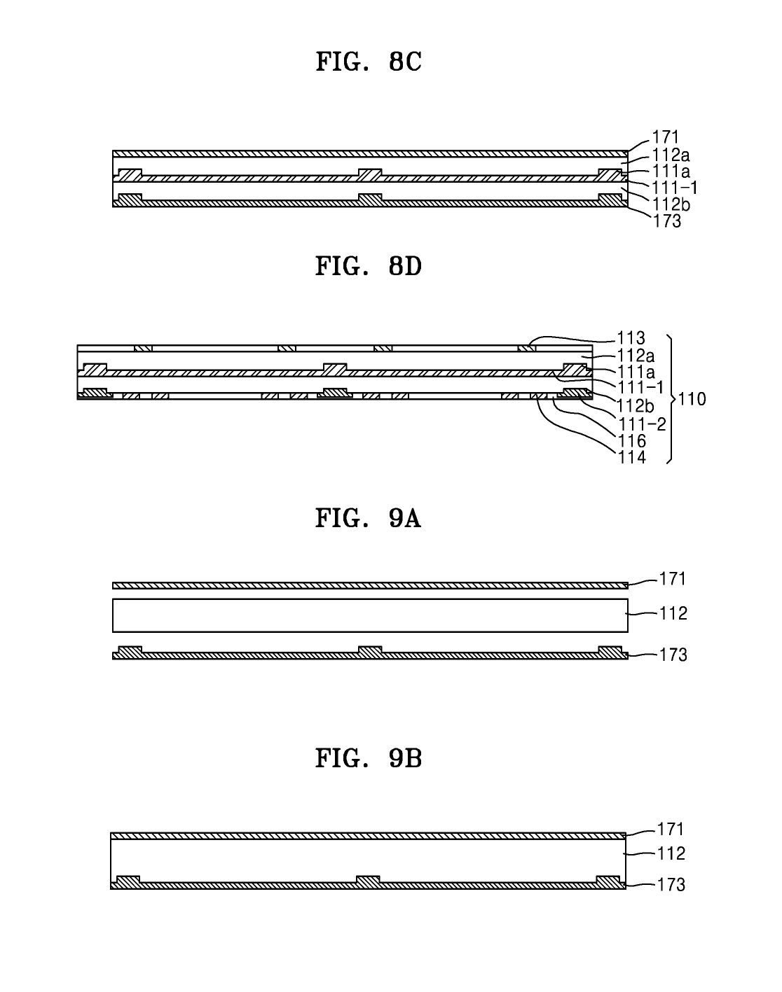

Referring to FIGS. 8A to 8D, the semiconductor package of FIG. 5 may be manufactured by performing the following process.

Referring to FIG. 5 and FIGS. 8A to 8C, the prepared first ground layer 111-1 and the first metal foil 171 are laminated and the first body portion 112a is interposed therebetween. The first metal foil 171 may use a plane metal foil, which has conductivity and a certain thickness. Next, the prepared first ground layer 111-1 and a third metal foil 173 are laminated and the second body portion 112b is interposed therebetween. The third metal foil 173 may use a metal foil on which a protruding portion is generated through substantially the same process as that of FIGS. 7A to 7D, as the plane metal foil, which has conductivity and a certain thickness. A part of the third metal foil 173 may act as a path to ground an electromagnetic wave by forming the second ground layer 111-2 later.

Referring to FIGS. 5 and 8D, the first wiring 113 is formed by patterning the first metal foil 171 through an etching process such as a photolithography process. Furthermore, the second wiring 114 and the second ground layer 111-2 are also formed by patterning the third metal foil 173 through the etching process such as the photolithography process. The semiconductor package may be manufactured by performing the process of FIGS. 7I to 7K.

The solder resist layer 116 may be formed so as not to expose the second ground layer 111-2 to the outside and the solder resist layer 116 is formed so as not to cover the second wiring 114.

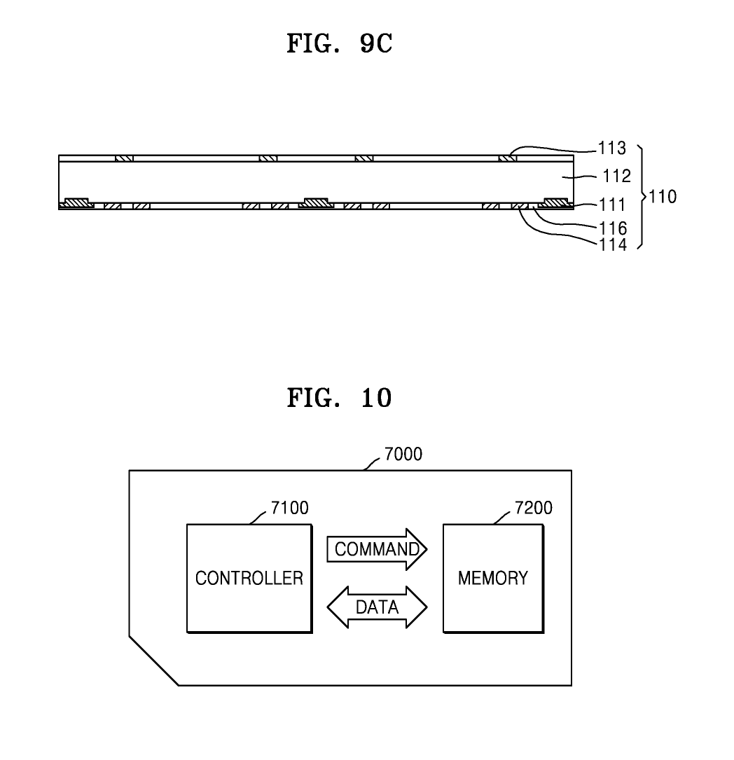

Referring to FIGS. 9A to 9C, the semiconductor package of FIG. 6 may be manufactured by performing the following process.

Referring to FIGS. 9A and 9B, the first metal foil 171 and the third metal foil 173 are laminated and the body portion 112 is interposed therebetween. The first metal foil 171 may use a plane metal foil, which has conductivity and a certain thickness. The third metal foil 173 may use a metal foil on which a protruding portion is generated through substantially the same process as that of FIGS. 7A to 7D, as the plane metal foil, which has conductivity and a certain thickness. A part of the third metal foil 173 may act as a path to ground an electromagnetic wave by forming the ground layer 111 later.

Referring to FIG. 9C, the first wiring 113 is formed by patterning the first metal foil 171 through an etching process such as a photolithography process. Furthermore, the second wiring 114 and the ground layer 111 are also formed by patterning third metal foil 173 through the etching process such as the photolithography process. The semiconductor package may be manufactured by performing the process of FIGS. 7I to 7K.

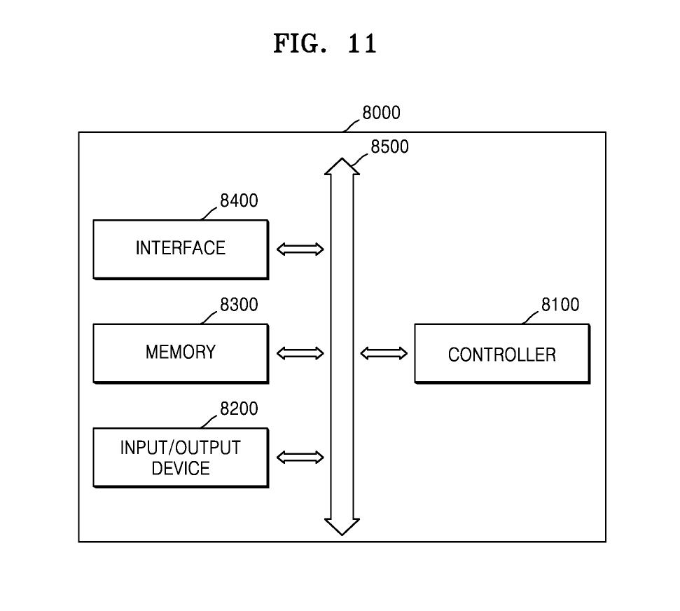

FIG. 10 illustrates a structural block diagram of an electronic device such as a memory card 7000 according to an exemplary embodiment of the inventive concept.

Referring to FIG. 10, a controller 7100 and a memory 7200 may be disposed in the memory card 7000 so as to exchange an electrical signal. For example, when the controller 7100 gives commands, the memory 7200 may transmit data. The controller 7100 or the memory 7200 may include a semiconductor package according to one of exemplary embodiments of the inventive concept. The memory 7200 may include a memory array or a memory array bank.

The card 7000 may be used for various cards, for example, a memory stick card, a smart media card (SM), a secure digital card (SD), a mini secure digital card (mini SD), or a memory apparatus such as a multi-media card (MMC).

FIG. 11 is a structural block diagram of an electronic system 8000 according to an exemplary embodiment of the inventive concept.

Referring to FIG. 11, the electronic system 8000 may include a controller 8100, an input/output device 8200, a memory 8300, and an interface 8400. The electronic system 8000 may be a mobile system or a system, which transmits or receives information. The mobile system may be a personal digital assistant (PDA), a portable computer, a web tablet, a wireless phone, a mobile phone, a digital music player, or a memory card. The controller 8100 may perform a program and control the electronic system 8000. The controller 8100 may be, for example, a microprocessor, a digital signal processor, a microcontroller, or a similar device. The input/output device 8200 may be used to input or output data of the electronic system 8000.

The electronic system 8000 may be connected to an external device, for example, a personal computer (PC) or a network by using the input/output device 8200 and exchange data with the external device. The input/output device 8200 may be, for example, a keypad, a keyboard or a display. The memory 8300 may store a code and/or data for operation of the controller 8100 or data, which is processed by the controller 8100. The controller 8100 and the memory 8300 may include a semiconductor package according to one of exemplary embodiments of the inventive concept. The interface 8400 may be a transmission path for data between the electronic system 8000 and other external devices. The controller 8100, the input/output device 8200, the memory 8300, and the interface 8400 may communicate with each other via a bus 8500.

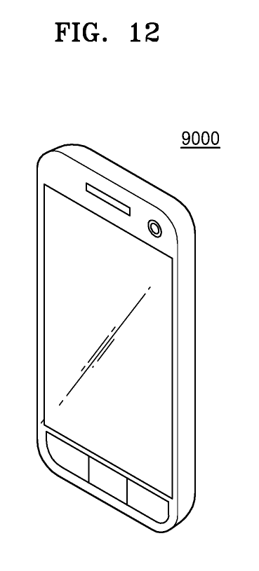

FIG. 12 is a perspective view of an electronic device to which a semiconductor package according to an exemplary embodiment of the inventive concept may be applied.

FIG. 12 illustrates an example of applying the electronic system 8000 of FIG. 11 to a mobile phone 9000. The electronic system 8000 of FIG. 11 may also be applied to a portable laptop computer, an MP3 player, a navigator, a portable multimedia player (PMP), a solid state disk (SSD), an automobile, or household appliance.

While various aspects of the inventive concept have been particularly shown and described with reference to exemplary embodiments thereof, it will be understood that various changes in form and details may be made therein without departing from the spirit and scope of the following claims.

What is claimed is:

1. A semiconductor package comprising:
a package substrate including a core formed of an electrically insulating material and an electrically conductive ground layer formed within the core;
a plurality of external terminals positioned to electrically connect circuitry in the package substrate to an external device external to the semiconductor package; and
one or more semiconductor chips stacked on and electrically connected to the package substrate;
a mold member disposed on the package substrate and surrounding the one or more semiconductor chips; and
an electromagnetic wave shield layer formed on side surfaces and on a top surface of the mold member and formed on side surfaces of the package substrate,
wherein the conductive ground layer is electrically connected to at least a first terminal of the plurality of external terminals, the first terminal electrically connected to circuitry of the one or more semiconductor chips designated for connecting to a ground, and
wherein the conductive ground layer has a plate shape, including a base portion and a lip portion formed of the same material, the lip portion extending above and/or below the base portion, and
wherein a side of the base portion of the conductive ground layer and a side of the lip portion of the conductive ground layer form part of a side surface of the package substrate, and contact the electromagnetic wave shield layer.

2. The semiconductor package of claim 1, wherein:
the electromagnetic wave shield layer entirely surrounds side surfaces and a top surface of the semiconductor package.

3. The semiconductor package of claim 2, wherein the one or more semiconductor chips are completely enclosed by a combination of the electromagnetic wave shield layer and the conductive ground layer.

4. The semiconductor package of claim 1, wherein the lip portion of the conductive ground layer extends in a direction perpendicular to the base portion of the conductive ground layer.

5. The semiconductor package of claim 1, wherein the core of the package substrate includes a first core portion located on an upper surface of the ground layer and a second core portion located on a lower surface of the ground layer.

6. The semiconductor package of claim 1, wherein the lip portion of the conductive ground layer extends along an outer periphery of the conductive ground layer.

7. The semiconductor package of claim 6, wherein the lip portion extends along the outer periphery of the ground layer both above and below the base portion of the conductive ground layer.

8. The semiconductor package of claim 1, wherein:
the lip portion extends discontinuously along the outer periphery of the conductive ground layer.

9. The semiconductor package of claim 1, further comprising:
at least a first vertical conductive line electrically connected to a first external terminal of the plurality of external terminals, and electrically connected to the conductive ground layer.

10. The semiconductor package of claim 1, wherein:
the plurality of external terminals are below the conductive ground layer and the one or more semiconductor chips are above the conductive ground layer.

11. The semiconductor package of claim 1, wherein:
an electromagnetic wave shield layer comprises a first electromagnetic wave shield layer contacting the side surface of the package substrate, and a second electromagnetic wave shield layer surrounding the first electromagnetic wave shield layer.

12. A semiconductor package comprising:
a package substrate including a first body portion and a second body portion, each formed of an electrically insulating material, and a first ground layer formed of an electrically conductive material and formed between the first body portion and the second body portion;
a plurality of external terminals disposed below the first ground layer to electrically connect circuitry in the package substrate to an external device external to the semiconductor package;
one or more semiconductor chips disposed above the first ground layer and on the package substrate, and electrically connected to the package substrate; and
a mold member disposed on the package substrate and surrounding the one or more semiconductor chips; and
an electromagnetic wave shield layer formed on side surfaces and on a top surface of the mold member and formed on side surfaces of the package substrate,
wherein the first ground layer is electrically connected to at least a first terminal of the plurality of external terminals, the first terminal electrically connected to circuitry of the one or more semiconductor chips designated for connecting to a ground,
wherein the first ground layer has a plate shape, including a planar portion and protruding portion protruding from the planar portion, the planar portion and protruding portion formed of the same material, wherein the protruding portion extends above and/or below the planar portion, and
wherein the planar portion and the protruding portion of the first ground layer form part of a side surface of the package substrate and contact the electromagnetic wave shield layer.

13. The semiconductor package of claim 12, wherein:
the first body portion and second body portion of the package substrate form a core of the package substrate, such that the first ground layer is formed within the core.

14. The semiconductor package of claim 12, wherein the protruding portion of the first ground layer extends in a direction perpendicular to the planar portion of the first ground layer.

15. The semiconductor package of claim 12, wherein the protruding portion extends along an outer periphery of the first ground layer.

16. The semiconductor package of claim 15, wherein the protruding portion extends along the entire outer periphery of the first ground layer.

17. The semiconductor package of claim 12, further comprising:
a second ground layer formed on a lower surface of the second body portion and including a planar portion and a protruding portion protruding from the planar portion of the second ground layer,
wherein the planar portion and the protruding portion of the second ground layer contact the electromagnetic wave shield layer.

18. The semiconductor package of claim 12, further comprising:
at least a first vertical conductive line electrically connected to a first external terminal of the plurality of external terminals, and electrically connected to the first ground layer.

19. A semiconductor device comprising:
a package substrate including a core portion formed of an electrically insulating material, and an electrically conductive ground layer formed in the core portion;
a plurality of external terminals disposed below the conductive ground layer to electrically connect circuitry in the package substrate to an external device external to the semiconductor package;
one or more semiconductor chips disposed above the conductive ground layer, and electrically connected to the package substrate;
a mold member disposed on the package substrate and surrounding the one or more semiconductor chips; and
an electromagnetic wave shield layer formed on side surfaces and on a top surface of the semiconductor package, and contacting the planar portion and protruding portion of the conductive ground layer,
wherein the conductive ground layer is electrically connected to at least a first terminal of the plurality of external terminals, the first terminal electrically connected to a ground, and
wherein the conductive ground layer has a plate shape, including a planar portion and protruding portion protruding from the planar portion, the planar portion and protruding portion formed of the same material, wherein the protruding portion extends above and/or below the planar portion.

20. The semiconductor device of claim 19, wherein:
the planar portion and the protruding portion of the conductive ground layer form part of a side surface of the package substrate.
